(19) United States
(12) Patent Application Publication
(10) Pub. No.: US 2024/0232711 A1
(43) Pub. Date: Jul. 11, 2024

(54) TECHNIQUES FOR TRAINING AND ANALYZING A MACHINE LEARNING MODEL

(71) Applicant: Stats LLC, Chicago, IL (US)

(72) Inventors: Dominic Oliver, London (GB); Michael Stöckl, Munich (DE); Arun Murali, Bengaluru (IN); Patrick Joseph Lucey, Chicago, IL (US)

(73) Assignee: Stats LLC, Chicago, IL (US)

(21) Appl. No.: 18/404,159

(22) Filed: Jan. 4, 2024

Related U.S. Application Data
(60) Provisional application No. 63/478,852, filed on Jan. 6, 2023.

(51) Int. Cl. G06N 20/00

(52) U.S. Cl. CPC G06N 20/00

(57) ABSTRACT

Disclosed techniques relate to improving predictions of machine learning models. In an example, a method involves receiving, from a machine learning model, predictions associated with a class of scenarios. The method includes identifying, in response to receiving the predictions, a subset of the class of scenarios that are beyond a threshold tolerance of accuracy. The method includes based on identifying the subset of the class of scenarios a training data set that includes emphasized event data from a plurality of historical sporting events. The method includes generating an updated machine learning model and deploying the updated machine learning model.

### CROSS-REFERENCE TO RELATED APPLICATIONS

This application claims the benefit of U.S. Provisional Application 63/478,852, filed on Jan. 6, 2023, the contents of which is hereby incorporated by reference for all purposes.

### FIELD OF THE DISCLOSURE

The present disclosure generally relates to machine learning models for sports applications, and in particular, various aspects of the present disclosure relate to improving predictions of a machine learning model.

### BACKGROUND

Machine learning techniques can be used to analyze sports data and make predictions. But with the proliferation of data, sports teams, commentators, and fans alike are more interested in identifying and classifying events that occur throughout a game or across a season. As more and more models configured to generate various predictions and metrics are developed, surfacing these predictions and metrics using machine learning techniques becomes increasingly valuable.

Unless otherwise indicated herein, the materials described in this section are not prior art to the claims in this application and are not admitted to be prior art, or suggestions of the prior art, by inclusion in this section.

### SUMMARY

In some aspects, the techniques described herein relate to a method that includes receiving, from a machine learning model, predictions associated with a class of scenarios; identifying, in response to receiving the predictions, a subset of the class of scenarios that are beyond a threshold tolerance of accuracy; based on identifying the subset of the class of scenarios, generating, by a computing system, a training data set that includes emphasized event data from historical sporting events; generating, by the computing system, an updated machine learning model by: identifying weights of the machine learning model, initializing the updated machine learning model using the weights, and training the updated machine learning model using the training data set; and deploying, by the computing system, the updated machine learning model.

In some aspects, the techniques described herein relate to a method that includes receiving updated predictions, associated with the class of scenarios, from the updated machine learning model; and outputting a visualization of the updated predictions.

In some aspects, the techniques described herein relate to a method that includes identifying, from the updated predictions, an additional subset of the class of scenarios that are beyond the threshold tolerance of accuracy; and based on identifying the additional subset of the class of scenarios, generating, by the computing system, an additional training data set that includes emphasized additional event data from the plurality of historical sporting events.

In some aspects, the techniques described herein relate to a method in which training the updated machine learning model using the training data set includes sequentially exposing the updated machine learning model to boosts of training data including the training data set and the additional training data set.

In some aspects, the techniques described herein relate to a method in which identifying the class of scenarios includes receiving an indication from a user that the machine learning model is generating predictions beyond the threshold tolerance of accuracy.

In some aspects, the techniques described herein relate to a method, in which identifying the class of scenarios includes: providing a first set of inputs to the machine learning model to generate a first prediction; providing a second set of inputs to the machine learning model to generate a second prediction; determining that the first prediction is within an expected range of a first expected prediction; and determining the second prediction is outside of a second expected range of a second expected prediction.

In some aspects, the techniques described herein relate to a method, in which the emphasized event data is generated by: providing initial training data used to train the machine learning model to an edge event machine learning model; providing the subset of the class of scenarios to the edge event machine learning model; and receiving the emphasized event data output by the edge event machine learning model based on the initial training data and the subset of the class of scenarios.

Additional objects and advantages of the disclosed aspects will be set forth in part in the description that follows, and in part will be apparent from the description, or may be learned by practice of the disclosed aspects. The objects and advantages of the disclosed aspects will be realized and attained by means of the elements and combinations particularly pointed out in the appended claims.

It is to be understood that both the foregoing general description and the following detailed description are exemplary and explanatory only and are not restrictive of the disclosed aspects, as claimed.

### BRIEF DESCRIPTION OF THE DRAWINGS

The accompanying drawings, which are incorporated in and constitute a part of this specification, illustrate various exemplary aspects and together with the description, serve to explain the principles of the disclosed aspects.

FIG. 1 is a block diagram illustrating a computing environment, in accordance with an aspect of the disclosed subject matter.

FIG. 2 is a flow diagram of a method for performing a counter-factual analysis using a machine learning model, in accordance with an aspect of the disclosed subject matter.

FIG. 3 illustrates an exemplary graphical user interface, in accordance with an aspect of the disclosed subject matter.

FIG. 4 illustrates an additional exemplary graphical user interface, in accordance with an aspect of the disclosed subject matter.

FIG. 5 is a block diagram of organization computing system, in accordance with an aspect of the disclosed subject matter.

FIG. 6 is a flow diagram illustrating a method for generating an updated prediction model, in accordance with an aspect of the disclosed subject matter.

FIGS. 7A-7C are diagrams that illustrate exemplary categories of outlier events, in accordance with an aspect of the disclosed subject matter.

FIG. 8 depicts a flow diagram for training a machine learning model, in accordance with an aspect of the disclosed subject matter.

FIG. 9 depicts an exemplary a computing device, in accordance with an aspect of the disclosed subject matter.

Notably, for simplicity and clarity of illustration, certain aspects of the figures depict the general configuration of the various aspects. Descriptions and details of well-known features and techniques may be omitted to avoid unnecessarily obscuring other features. Elements in the figures are not necessarily drawn to scale; the dimensions of some features may be exaggerated relative to other elements to improve understanding of the various aspects.

### DETAILED DESCRIPTION

Various aspects of the present disclosure relate to techniques for machine learning for sports applications. For instance, disclosed techniques involve training machine learning models to make predictions of certain events, deploying the appropriate machine learning models, and/or adjusting the machine learning models employed for predictions, as appropriate. Examples of adjustments include adjusting one or more weights, layers, and/or biases of a machine learning model, or selecting a different machine learning model for use.

In an example, disclosed techniques use machine learning to predict expected goals. Expected goals (xG) is a metric used in sport (e.g., soccer) that represents a quality of a chance or shot attempt by calculating the likelihood that a shot attempt will be scored from a particular position on a playing surface during a particular phase of play. The expected goals metric is typically based on several factors such as metrics from before a given shot is taken. Expected goals may be measured on a scale between zero and one, where zero represents a chance indicating that it is impossible to score and one represents a chance that a player would be expected to score every single time, based on input data. In some cases, an initial expected goals model can be acceptably accurate (e.g., in approximately 99.5% of measured cases). But there still exist several edge cases (or “edge events”) in which the accuracy of the expected goals model can be improved. These edge events may include, for example, unusual cases for which the expected goals model is not sufficiently trained such as in which training data used to train the expected goals model does not include a threshold number of similar examples. For such edge events, the expected goals model may not be trained with sufficient granularity to generalize predictions for similar unseen examples accurately (e.g., to meet a threshold accuracy). Disclosed techniques improve such predictions.

Technical advantages of the disclosed techniques include improvements to machine learning. For example, techniques disclosed herein provide an improvement to the existing expected goals model by boosting the training (or retraining) of the expected goals model, such that the expected goals model, or a newly trained model, can more accurately predict outcomes for edge events.

Disclosed techniques also improve evaluation of machine learning model performance. For example, one or more techniques disclosed herein provide an interactive/interpretable interface that may utilize the interpretable nature of sports data by providing outputs to one or more questions (e.g., “what-if” questions), which can identify where a machine learning model may have an accuracy beyond a threshold and may need improvement.

By contrast, when training machine learning models for sport applications, such as the expected goals model, the machine learning model is typically evaluated using standard evaluation metrics such as average log-loss, brier score, root-mean-square error (RMSE), etc. While such evaluation metrics are useful in establishing overall performance, such metrics are typically not able to highlight or identify issues around specific edge-cases or outliers. In the context of sports, it can be especially important to have robust performance in these situations as they are often the most interesting moments and will have the most attention. Existing methods of evaluations are not able to shine a light on these specific moments.

As used herein, a “machine learning model” generally encompasses instructions, data, and/or a model configured to receive input, and apply one or more of a weight, bias, classification, or analysis on the input to generate an output. The output may include, for example, a classification of the input, an analysis based on the input, a design, process, prediction, or recommendation associated with the input, or any other suitable type of output. A machine learning model is generally trained using training data, e.g., experiential data and/or samples of input data, which are fed into the model in order to establish, tune, or modify one or more aspects of the model, e.g., the weights, biases, criteria for forming classifications or clusters, or the like. Aspects of a machine learning model may operate on an input linearly, in parallel, via a network (e.g., a neural network), or via any suitable configuration.

The execution of the machine learning model may include deployment of one or more machine learning techniques, such as linear regression, logistic regression, random forest, gradient boosted machine (GBM), deep learning, and/or a deep neural network. Supervised and/or unsupervised training may be employed. For example, supervised learning may include providing training data and labels corresponding to the training data, e.g., as ground truth. Unsupervised approaches may include clustering, classification or the like. K-means clustering or K-Nearest Neighbors may also be used, which may be supervised or unsupervised. Combinations of K-Nearest Neighbors and an unsupervised cluster technique may also be used. Any suitable type of training may be used, e.g., stochastic, gradient boosted, random seeded, recursive, epoch or batch-based, etc.

While several of the examples herein involve certain types of machine learning, it should be understood that techniques according to this disclosure may be adapted to any suitable type of machine learning. It should also be understood that the examples above are illustrative only. The techniques and technologies of this disclosure may be adapted to any suitable activity.

Further, while various aspects are discussed with respect to soccer (e.g., a predicted total number of passes by a team during a game), such aspects are described are merely illustrative examples. Disclosed techniques are by no means limited to soccer. For example, the present aspects can be implemented for other sports or activities, such as football, basketball, baseball, hockey, cricket, rugby, tennis, and so forth.

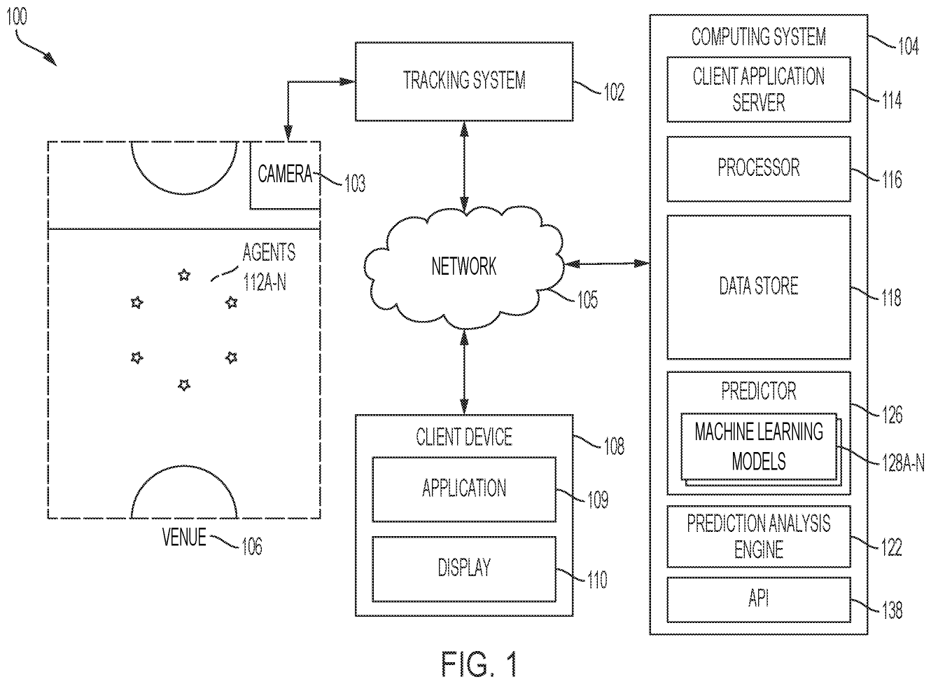

FIG. 1 is a block diagram illustrating a computing environment, in accordance with an aspect of the disclosed subject matter. Environment 100 includes tracking system 102, computing system 104, and client device 108 connected via network 105. In the example depicted, tracking system 102 obtains various measurements of game play, and transmits the measurements across network 105 to computing system 104, where the measurements can be used in conjunction with one or more machine learning models. In the example depicted, environment 100 is used to train various machine learning models to make predictions of certain events, deploy the appropriate machine learning models, and adjust the machine learning models employed for predictions as appropriate.

Tracking system 102 may be in communication with and/or may be positioned in, adjacent to, or near a venue 106. Non-limiting examples of venue 106 include stadiums, fields, pitches, and courts. Venue 106 includes agents 112A-N (players). Tracking system 102 may be configured to record the motions and actions of agents 112A-N on the playing surface, as well as one or more other objects of relevance (e.g., ball, referees, etc.). Although environment 100 depicts agents 112A-N generally as players, it will be understood that in accordance with certain implementations, agents 112A-N may correspond to players, objects, markers, and/or the like.

In some aspects, tracking system 102 may be an optically-based system using, for example, using camera 103. While one camera is depicted, additional cameras are possible. For example, a system of six stationary, calibrated cameras, which project the three-dimensional locations of players and the ball onto a two-dimensional overhead view of the court may be used.

In another example, a mix of stationary and non-stationary cameras may be used to capture motions of all agents 112A-N on the playing surface as well as one or more objects of relevance. Utilization of such tracking system (e.g., tracking system 102) may result in many different camera views of the court (e.g., high sideline view, free-throw line view, huddle view, face-off view, end zone view, etc.). In some aspects, tracking system 102 may corresponds to a broadcast feed of a given match. In such aspects, each frame of the broadcast feed may be stored in a game file. In some aspects, the game file may further be augmented with other event information corresponding to event data, such as, but not limited to, game event information (pass, made shot, turnover, etc.) and context information (current score, time remaining, etc.).

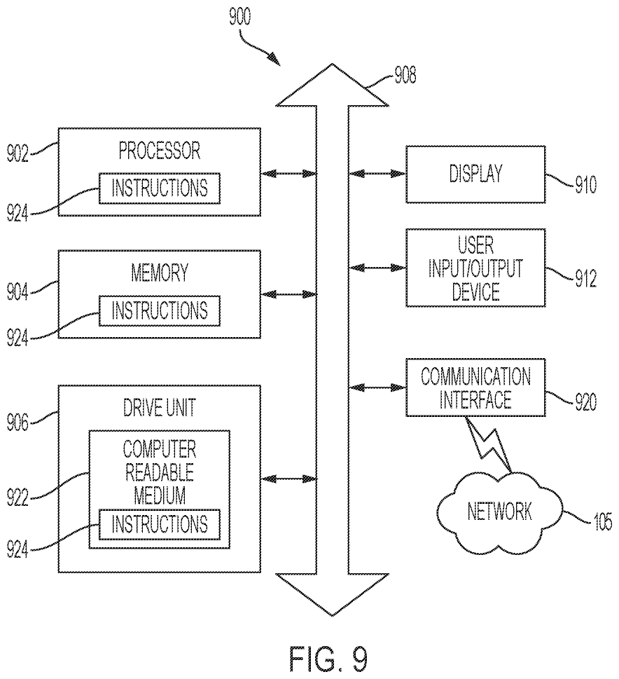

Tracking system 102 may be configured to communicate with computing system 104 via network 105. Computing system 104 may be configured to manage and analyze the data captured by tracking system 102. Computing system 104 may include a web client application server 114, a processor 116 (e.g., a preprocessor), a data store 118, a predictor 126 having one or more machine learning models 128a-n, a prediction analysis engine 122, and/or a third-party Application Programming Interface (API) 138. An example of computing system 104 is depicted with respect to FIG. 9.

Each of processor 116, predictor 120, and prediction analysis engine 122 may include or may be implemented using one or more software modules. The software modules may be collections of code or instructions stored on a media (e.g., memory of computing system 104) that represent a series of machine instructions (e.g., program code) that implements one or more algorithmic operations. Such machine instructions may be the actual computer code the processor of computing system 104 interprets to implement the instructions or, alternatively, may be a higher level of coding of the instructions that is interpreted to obtain the actual computer code. In some cases, functionality implemented by the software modules may be implemented via one or more hardware components. One or more aspects of an example algorithm may be performed by the hardware components (e.g., circuitry) itself, rather as a result of the instructions.

Data store 118 may be configured to store one or more game files. Each game file may include video data of a given match (e.g., a game, a competition, a round, etc.) and/or may include tracking data generated by tracking system 102 or in response to data generated by tracking system 102. Video data may correspond to data for an ongoing match or data for a previous or historical match. For example, the video data may correspond to video frames captured by tracking system 102. In some aspects, the video data may correspond to broadcast data of a given match, in which case, the video data may correspond to video frames of the broadcast feed of a given match.

Processor 116 may be configured to process data retrieved from data store 118. For example, processor 116 may be configured to generate game files stored in data store 118. For example, processor 116 may be configured to generate a game file based on data captured by tracking system 102. In some aspects, processor 116 may further be configured to store tracking data associated with each match in a respective game file. Tracking data may, at least in part, refer to the (x, y) coordinates of players and objects (e.g., balls) on or around the playing surface during a given match. In some aspects, processor 116 may receive tracking data directly from tracking system 102. In some aspects, processor 116 may derive tracking data from the broadcast feed of the game.

According to certain aspects, a game file may include one or more match data types. A match data type may include, but is not limited to, position data (e.g., player position, object position, etc.) change data (e.g., changes in position, changes in players, changes in objects, etc.), trend data (e.g., player trends, position trends, object trends, team trends, etc.), play data, etc. A game file may be a single game file or may be segmented (e.g., grouped by one or more data type, grouped by one or more players, grouped by one or more teams, etc.). Processor 116 and/or data store 118 may be operated (e.g., using applicable code) to receive tracking data in a first format, store game files in a second format, and/or output game data (e.g., to predictor 126) in a third format. For example, processor 116 may receive an intended destination for game data (or data stored in data store 118 in general) and may format the data into a format acceptable by the intended destination.

Predictor 120 can include one or more machine learning models 128a-n. Predictor 120 may be configured to train or retrain machine learning models 128a-n, such as an expected goals model. An expected goals model is configured to generate an expected goals metric (e.g., a value or distribution) that measures a quality or a chance of a shot attempt by calculating the likelihood that the shot attempt will have a positive outcome (e.g., a goal or score) from a particular position on the playing surface during a particular phase of play. In some aspects, the expected goals metric may be measured on a scale between zero and one, where zero represents a chance that there is zero probability that a shot attempt will result in a positive outcome, and one represents a chance that a player would be expected to score every single time.

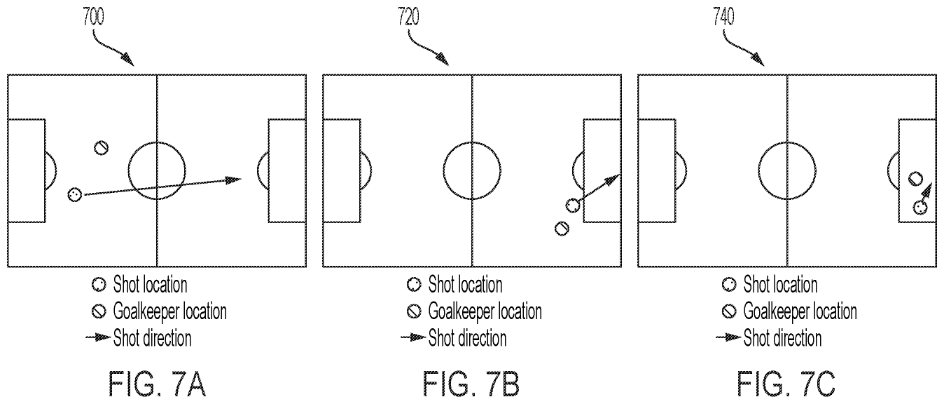

As discussed above, an initial expected goals model can be accurate for the vast majority of cases. Such an initial expected goals model may be trained based on historical or simulated match data. However, such an initial expected goals model may be less likely to accurately generate an expected goals prediction for outlier or edge events. Examples of outlier cases are discussed further with respect to FIGS. 7A-C. To account for outlier cases, predictor 120 may be configured to improve the accuracy of an initial expected goals model by sequentially exposing the initial expected goals model to new boosts of data according to characteristics of edge events. Such training or retraining process may improve the accuracy of the expected goals model.

Prediction analysis engine 122 may be configured to provide insights related to prediction models (e.g., machine learning models 128a-n). With the rise of machine learning algorithms, which have a prime focus on providing the most accurate predictions, often these approaches are “black boxes” which makes it difficult to understand how the predictions (or the decisions which are based on predictions) are made. As more decision-making is being based on machine learning approaches, a focus has been on making the predictions understandable, interpretable, and explainable.

Prediction analysis engine 122 may utilize a counter-factual approach to explain the predictions of a model or the impact of features within a model. For example, in operation, prediction analysis engine 122 may identify a prediction model. Prediction analysis engine 122 may identify a prediction model from a set of prediction models. The prediction model may be identified based on a desired output, based on a match being analyzed, based on models a given user or account has previously reviewed (e.g., based on a user or account profile), etc. In some aspects, the prediction model may be an expected goals model. Using the prediction model, prediction analysis engine 122 may provide or receive a first set of inputs to generate a first prediction. Prediction analysis engine 122 may then change some of the input features to generate a second prediction. Such changed inputs may be a result of a user input, a desired outcome, a change to event data (e.g., a change to a match attribute, a change to a player attribute, etc.) Prediction analysis engine 122 may then compare the first prediction to the second prediction to identify how changing an input or set of inputs affected the output.

In some aspects, to assist end users, prediction analysis engine 122 may provide users with an interactive user interface that may allow end users to modify inputs to machine learning models 128a-n. Based on the inputs provided through the interactive user interface, prediction analysis engine 122 may generate predictions using the selected machine learning model. According to an aspect, the selected machine learning model may be selected from a set of machine learning models based on and/or in response to the inputs provided via the user interface. Prediction analysis engine 122 may then generate graphical representations of outputs based on the provided set of inputs. In this manner, an end user may receive a visualization that depict show given inputs affect outputs of the machine learning model.

In some aspects, prediction analysis engine 122 may allow end users or an automated system to identify edge events. As discussed above, an edge event may refer to a situation or set of inputs to a machine learning model that generates an unexpected output (e.g., an output outside an expected range). In this manner, prediction analysis engine 122 may allow an end user or an automated system to identify themes or groups of situations for fine tuning the machine learning model. Continuing with the above example, prediction analysis engine 122 may allow an end user or automated system to determine that expected goals model is less accurate for certain situations, such as a higher expected goals metric than expected when the goalkeeper is very far away from the goal and behind the shot at the point the shot was taken. Once these features are identified, predictor 120 may leverage this information to generate more accurate prediction models that are able to handle the edge events.

According to an aspect, prediction analysis engine 122 may receive an identified edge event. The edge event may be provided by a user or may be determined by an automated system. An automated system may be an algorithmic system or may be an edge event machine learning model that outputs edge events or edge event types based on training data input and/or user inputs. For example, an automated system may identify and/or provide an edge event (e.g., a type of play, player position, a formation, an object location relative to another object or one or more players, etc.) based on historical or simulated data analysis.

According to this example, the automated system may analyze training data used to train an initial machine learning model (e.g., an initial expected goals model). Based on the analysis, a determination may be made that a given event type (e.g., a type of play, player position, a formation, an object location relative to another object or one or more players, etc.) occurs less than a threshold amount or percent of occurrences (e.g., relative to all or a subset of all events). The threshold amount of occurrences may correspond to a number of times the edge event type occurs, an amount of time corresponding to the given event type relative to an overall time associated with the training data, a number of matches the given event type occurs, and/or the like. The given event type may be identified as an edge event based on the amount of occurrences being below the threshold amount of occurrences.

According to an aspect, an edge event type may further be identified based on a given event type occurring less than the threshold amount of occurrences and, in addition, the given event type being associated with a key event a key event threshold number of times. A key event may be an event that is more pivotal in determining a match outcome with respect to other events during a given match. For example, a key event may be determined based on an excitement level associated with the key event, the key event resulting in a threshold change in score probability, the key event resulting in a threshold change in win or loss probability, and/or the like. A given event type may be identified as an edge event based on the given event type's temporal proximity to a key event, the given event type being a key event, the given event type causing a key event, and/or the like.

An initial machine learning model (e.g., an initial expected goals model) may be retrained based on edge events and/or edge event types. As an example, an edge event machine learning model may output edge event types, as discussed herein. The initial training data used to train the initial machine learning model or new training data may be analyzed to identify edge events included in the training data based on the edge events or edge event types output by the edge event training model. The edge events may for training data may be output by an event machine learning model trained to output given events from the training data based on inputs that include edge events or edge event types. The initial machine learning model may be retrained by weighing the edge events of the training data (e.g., initial training data and/or new training data) higher than other events. Accordingly, edge events in such training data may be emphasized such that the initial machine learning model is retrained with an added emphasis applied to the edge events. The resulting machine learning model (e.g., an updated expected goals model) may, therefore, be trained to generate outputs that better reflect the occurrence of outlier scenarios corresponding to edge events.

Client device 108 may be in communication with computing system 104 via network 105. Client device 108 may be operated by a user. For example, client device 108 may be a mobile device, a tablet, a desktop computer, or any computing system having the capabilities described herein. Users may include, but are not limited to, individuals such as, for example, subscribers, clients, prospective clients, or customers of an entity associated with computing system 104, such as individuals who have obtained, will obtain, or may obtain a product, service, or consultation from an entity associated with computing system 104.

Client device 108 may include one more applications 109. Application 109 may be representative of a web browser that allows access to a website or a stand-alone application. Client device 108 may access application 109 to access one or more functionalities of computing system 104. Client device 108 may communicate over network 105 to request a webpage, for example, from web client application server 114 of computing system 104. For example, client device 108 may be configured to execute application 109 to access content managed by web client application server 114. The content that is displayed to client device 108 may be transmitted from web client application server 114 to client device 108, and subsequently processed by application 109 for display through a graphical user interface (GUI) of client device 108. Client device 108 may communicate over network 105 to request a webpage, for example, from web client application server 114 of computing system 104. For example, client device 108 may be configured to execute application 109 to perform a counter factual analysis on predictor 120 via a quality assurance interface. In another example, client device 108 may be configured to execute application 109 to generate an expected goals prediction using predictor 120. The content that is displayed to client device 108 may be transmitted from web client application server 114 to client device 108, and subsequently processed by application 109 for display through a graphical user interface (GUI) of client device 108.

Client device may include display 110. Examples of display 110 include, but are not limited to, computer displays, Light Emitting Diode (LED) displays, and so forth. Output or visualizations (e.g., a GUI) generated by application 109 can be displayed on display 110.

Functionality of sub-components illustrated within computing system 104 can be implemented in hardware, software, or some combination thereof. For example, software components may be collections of code or instructions stored on a media such as a non-transitory computer-readable medium (e.g., memory of computing system 104) that represent a series of machine instructions (e.g., program code) that implements one or more method operations. Such machine instructions may be the actual computer code the processor of computing system 104 interprets to implement the instructions or, alternatively, may be a higher level of coding of the instructions that is interpreted to obtain the actual computer code. The one or more software modules may also include one or more hardware components. Examples of components include processors, controllers, signal processors, neural network processors, and so forth.

Network 105 may be of any suitable type, including individual connections via the Internet, such as cellular or Wi-Fi networks. In some aspects, network 105 may connect terminals, services, and mobile devices using direct connections, such as radio frequency identification (RFID), near-field communication (NFC), Bluetooth™, low-energy Bluetooth™ (BLE), Wi-Fi™, ZigBee™, ambient backscatter communication (ABC) protocols, USB, WAN, or LAN. Because the information transmitted may be personal or confidential, security concerns may dictate one or more of these types of connection be encrypted or otherwise secured. In some aspects, however, the information being transmitted may be less personal, and therefore, the network connections may be selected for convenience over security.

Network 105 may include any type of computer networking arrangement used to exchange data or information. For example, network 105 may be the Internet, a private data network, virtual private network using a public network and/or other suitable connection(s) that enables components in environment 100 to send and receive information between the components of environment 100.

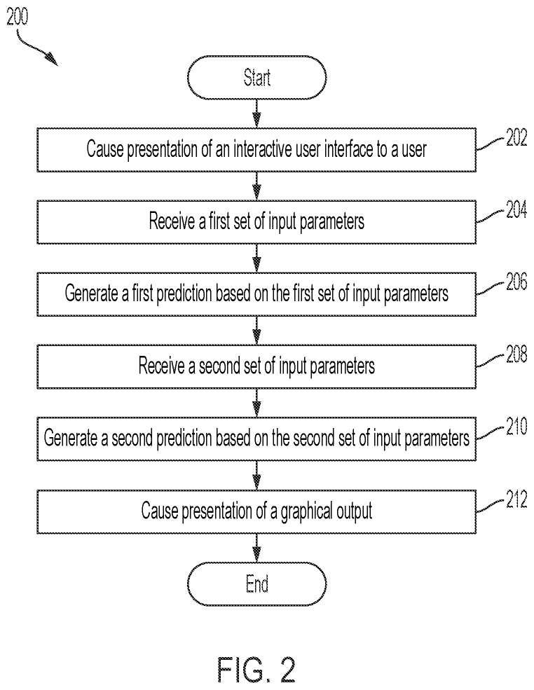

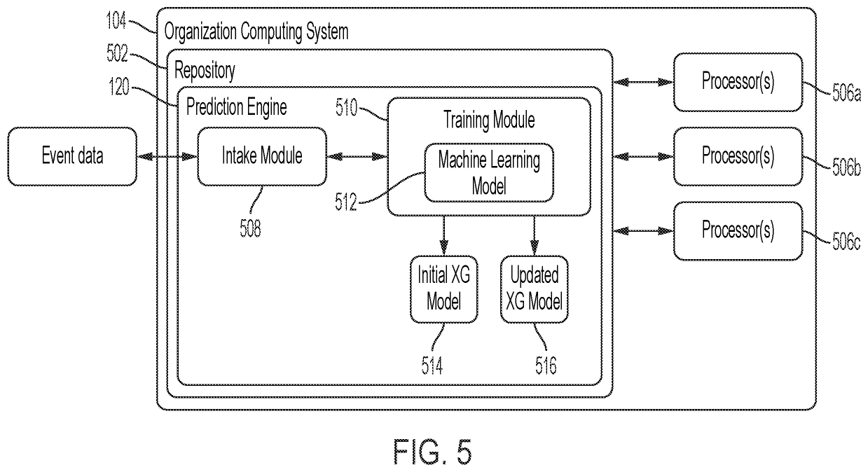

FIG. 2 is a flow diagram of a method for performing a counter-factual analysis using a machine learning model, in accordance with an aspect of the disclosed subject matter. Method 200 can be performed by any computing system, including any computing system disclosed herein, such as computing system 104, or those discussed with respect to FIGS. 5 and 9.

Method 200 includes various operations, indicated by blocks. It will be appreciated that in some cases, not all operations are completed. For example, some operations can be skipped. Additionally or alternatively, some operations can be performed multiple, times, for example, in a loop. Other variations are possible.

At block 202, computing system 104 may cause presentation of an interactive user interface to a user. For example, prediction analysis engine 122 may provide a client device 108 with an interactive user interface display 110 to present to a user via application 109. The interactive user interface may allow the end user to modify inputs to various machine learning models. In some aspects, the interactive user interface may allow a user to select or define categories of inputs to the machine learning model. For example, when the machine learning model is an expected goals model, the categories of inputs may include: shot type, shot characteristics, assist type, clarity, pressure, etc.

At block 204, computing system 104 may receive a first set of inputs for a first set of input categories. For example, prediction analysis engine 122 may receive a first set of example inputs to be provided to a machine learning model. The first set of inputs may be provided by tracking system 102, data store 118, another component (e.g., of FIG. 1), or a user (e.g., via the user interface presented at block 202).

At block 206, computing system 104 may generate a first prediction based on the example inputs. For example, predictor 120 may provide the first set of inputs to the machine learning model for generation of an output. Using a specific example, predictor 120 may provide the first set of inputs to an expected goals model for the expected goals model to generate an expected goals metric. It will be understood that such inputs received at block 204 may be used to generate the first prediction at block 206 in addition to one or more other inputs (e.g., inputs related to game play as received from tracking system 102, historical inputs, simulated inputs, etc.).

At block 208, a computing system may receive a second set of inputs for the first set of input categories. For example, prediction analysis engine 122 may receive a second set of example inputs to be provided to a machine learning model. In some aspects, the second set of example inputs may include at least one input that is different from the first set of example inputs. According to some aspects, the second set of inputs may be provided by a user (e.g., via the user interface) or an automated system, as discussed herein. According to an aspect, the second set of inputs may be edge events or edge event types, as discussed herein.

At block 210, computing system 104 may generate a second prediction based on the second set of example inputs. For example, predictor 120 may provide the second set of inputs to the machine learning model for generation of a second output. Using a specific example, predictor 120 may provide the second set of inputs to an expected goals model for the expected goals model to generate a second expected goals metric. As discussed herein, the second expected goals metric may be generated based on the machine learning model (e.g., expected goals model) emphasizing the edge events received at block 208. Alternatively, the second expected goals metric may be generated based on an example scenario of events corresponding to the second set of example inputs.

At block 212, computing system 104 may cause presentation of graphical output. For example, prediction analysis engine 122 may generate a graphical output that visually compares the first output and the second output. In this manner, an end user may be able to see how the change to an input affected the output from the machine learning model.

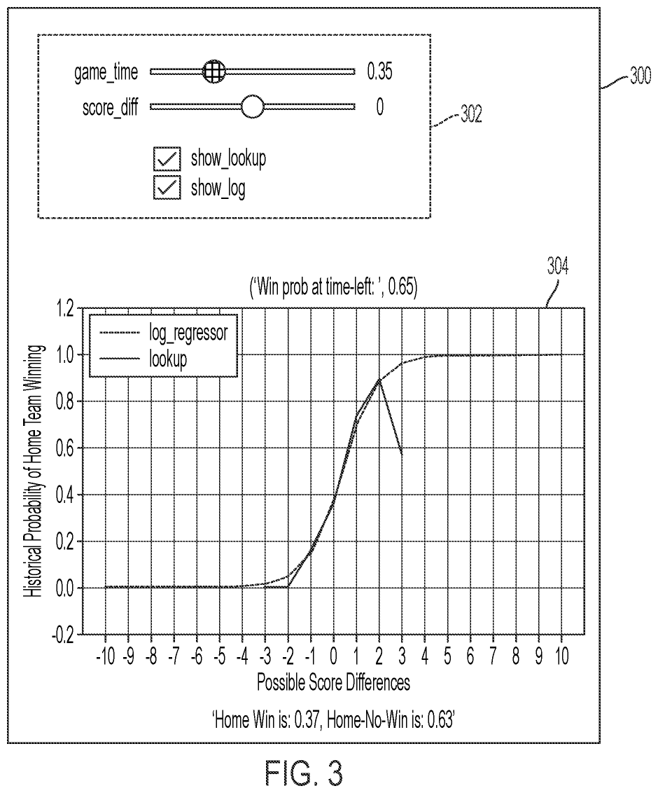

FIG. 3 illustrates an exemplary graphical user interface 300, in accordance with an aspect of the disclosed subject matter. GUI 300 may correspond to a prediction analysis engine interface generated by prediction analysis engine 122. For example, prediction analysis engine 122 may generate GUI 300 to be displayed to a user

As shown, GUI 300 may correspond to a prediction analysis engine interface corresponding to a prediction model that is trained to generate a win probability for a team. GUI 300 may include a set of input fields 302. The set of input fields 302 may allow a user to provide example inputs to the win probability prediction model. In some aspects, input fields 302 may take the form of sliders. In some aspects, input fields 302 may take the form of a text-based input field. In some aspects, input fields 302 may take the form of dropdown menus. Based on the inputs provided to input fields 302, the prediction model being analyzed may generate a prediction output. In the current example, a win probability model may generate a win probability based on the input provided in input fields 302.

GUI 300 may further include graphical element 304. Graphical element 304 may correspond to a visualization of an output generated by the prediction model being analyzed. As shown, graphical element 304 may visually indicate how inputs conform to historical data. Graphical element 304 depicts a comparision of a baseline nearest neighbor's approach (as indicated by “lookup”) as compared to a logistic regression (as indicated by “log_regressor”). Graphical element 304 can be based on historical data or live data. In some cases, one or more components of graphical element 304 are dispayed on a user interface.

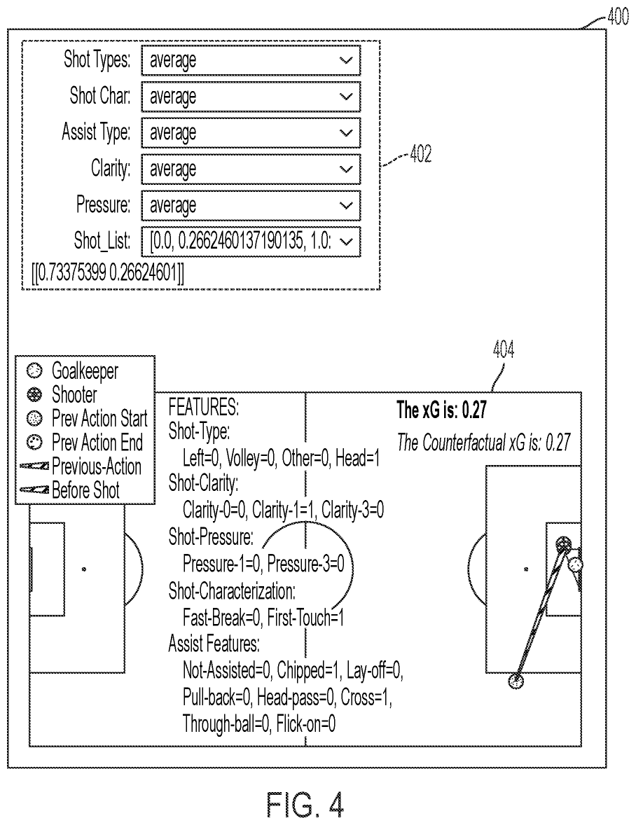

FIG. 4 illustrates an additional exemplary graphical user interface 400, in accordance with an aspect of the disclosed subject matter. GUI 400 may correspond to a prediction analysis engine interface generated by prediction analysis engine 122. For example, prediction analysis engine 122 may generate GUI 400 to be displayed to a user

As shown, GUI 400 may correspond to a prediction analysis engine interface corresponding to a prediction model that is trained to generate an expected goals prediction for a team. Via GUI 400, a user may be able to test a machine learning model to determine how accurately (or inaccurately) a machine learning model can generate prediction for certain classes of inputs, such as outlier events or edge events. GUI 400 may include a set of input fields 402. The set of input fields 402 may allow a user to provide example inputs to the win probability prediction model. In some aspects, input fields 402 may take the form of sliders. In some aspects, input fields 402 may take the form of a text-based input field. In some aspects, input fields 402 may take the form of dropdown menus. Based on the inputs provided to input fields 402, the prediction model being analyzed may generate a prediction output. In the current example, a win probability model may generate a win probability based on the input provided in input fields 402. In the specific example discussed herein, an expected goals model may generate an expected goals prediction based on the input provided in input fields 402.

GUI 400 may further include graphical element 404. Graphical element 404 may correspond to a visualization of an output generated by the prediction model being analyzed. As shown, graphical element 404 may visually indicate how the output compares to an expected output. GUI 400 may allow one to understand how individual input features may impact the output of an expected goals model. For example, GUI 400 may be used to further explore the expected goals model to understand whether the expected goals model has any other outliers (e.g., blind spots). As discussed herein, such outliers may be used to identify edge events to retrain a given machine learning model.

Using a more detailed example, there may be a scenario where the system generates an expected goals prediction. For example, predictor 120 may generate values of the various features for the given shot as well as the expected goals and counterfactual expected goals values. For example, Clarity=1 implies that this was a high clarity shot. Using the dropdown menus of GUI 400, an operator could change this to a low clarity shot (e.g., Clarity=3) and re-predict the expected goals for this shot. This would then provide the counterfactual expected goals value, such that the expected goals value if this shot actually was a lower clarity shot. An automated system or user can then compare this prediction to the prediction generated by predictor 120 for the original shot, thus providing an example to understand the role of clarity for this shot and predictor 120 in general. The same process can be repeated for all the features of predictor 120 to understand how predictor 120 may behave in different scenarios.

Accordingly, by using GUI 400, an automated system or end user may be able to identifier outlier events or edge events that have less than desired accuracy.

FIG. 5 is a block diagram of an exemplary computing system, in accordance with an aspect of the disclosed subject matter. An example computing system is computing system 104 of FIG. 1. As shown, computing system 104 may include a repository 502. The repository 502 can include one or more data storage nodes that may include instructions. The repository 502 can interact with processors 506a, 506b, and/or 506c to implement predictor 120 as described herein.

Predictor 120 may be configured to train and/or retrain a machine learning model. Although a configuration specific to an expected goals (xG) model is shown in FIG. 5, it will be understood that predictor 120 may be used to train and/or retrain any applicable machine learning model. Predictor 120 may include intake module 508 and training module 510. Each of intake module 508 and training module 510 may include one or more software modules. The one or more software modules may be collections of code or instructions stored on a media (e.g., memory of computing system 104) that represent a series of machine instructions (e.g., program code) that implements one or more algorithmic operations. Such machine instructions may be the actual computer code the processor interprets to implement the instructions or, alternatively, may be a higher level of coding of the instructions that is interpreted to obtain the actual computer code. The one or more software modules may also include one or more hardware components. One or more aspects of an example algorithm may be performed by the hardware components (e.g., circuitry) itself, rather than as a result of the instructions.

Intake module 508 may be configured to receive event data from processor 116. In some aspects, the event data may include event data that overlaps with the event data used to train an initial machine learning model such as initial expected goals model 514. In some aspects, the event data may include further event data (e.g., edge event data) that was not used to train initial expected goals model 514, as discussed herein. In some aspects, intake module 508 may be configured to generate one or more training sets based on the event data (e.g., edge event type weighted training data). For example, intake module 508 may be configured to identify subsets of event data that correspond to specific categories of outlier events, as discussed herein. Exemplary categories of outlier events may include, but are not limited to, long shots with the goalkeeper way off their line (e.g., tracking back from a corner), closer range shots where the goalkeeper is caught further away from the shot than the shooter, tight angle shots, and the like.

Intake module 508 may generate training data sets for each theme based on the identified subsets of event data. The training data sets may include event data directed to each theme. Exemplary event data may include, but is not limited to clarity features (e.g., players between the shot and the goal), pressure (e.g., pressure being put on the shooter either time-wise or defensively), goalkeeper features (e.g., distance of goalkeeper to goal/shot/line of sight, angle of goalkeeper to shot, etc.), shot location features (e.g., distance and/or angle of shot to goal), shot type (e.g., volley, header, left foot, right foot, etc.), assist features (e.g., pullback, lay off, cross, throw in, etc.), previous action location (e.g., deflections), contextual features (e.g., shot follows a rebound, first touch, set play, etc.). In some aspects, intake module 508 may supplement the training data sets with normally distributed noise around coordinate related features.

Training module 510 may be configured to train machine learning model 512 to generate an expected goals model that is able to generate an expected goals metric with an increased accuracy for outlier cases. It will be understood that training module 510 and/or machine learning model 512 may be instances of machine learning models 128a-n, as discussed herein. Rather than train machine learning model 512 from scratch, the present disclosure provides a “warm start” technique to training. For example, training module 510 may identify the existing weights and biases in initial expected goals model 514 and may apply the existing weights and biases to machine learning model 512 to warm up the model. One of the benefits of utilizing the warm start approach is that it maintains the accuracy initial expected goals model 514 for the vast majority of shots but improve predictions for the identified edge events. In this manner, updated expected goals model 516 may provide a better predictor of goals across leagues/seasons/teams/players when taken in aggregate.

Training module 510 may then train machine learning model 512 using boosts of training data (e.g., edge event type weighted training data). For example, training module 510 may train machine learning model 512 based on theme, in order of priority. As training progresses, the initial weights of machine learning model 512 may be adjusted to account for the boost of training data. Once trained, updated expected goals model 516 may be deployed.

In some aspects, machine learning model 512 may be representative of a multi-layer perceptron neural network. In such aspects, training module 510 may identify existing weights of each node of the multi-layer perceptron neural network underlying initial expected goals model 514 and may apply those weights to corresponding nodes of the multi-layer perceptron neural network underlying machine learning model 512. In some aspects, machine learning model 512 may be representative of a regression-based model.

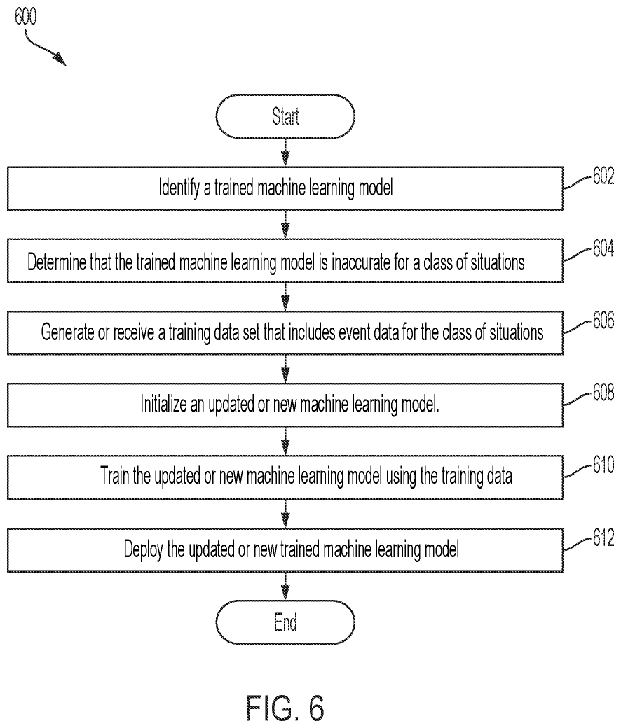

FIG. 6 is a flow diagram illustrating a method 600 for generating an updated prediction model, in accordance with an aspect of the disclosed subject matter. Method 600 can be performed by any computing system, including any computing system disclosed herein, such as computing system 104, and/or computing device 900.

Method 600 includes various operations, indicated by blocks. It will be appreciated that in some cases, not all operations are completed. For example, some operations can be skipped. Additionally or alternatively, some operations can be performed multiple, times, for example, in a loop. Other variations are possible.

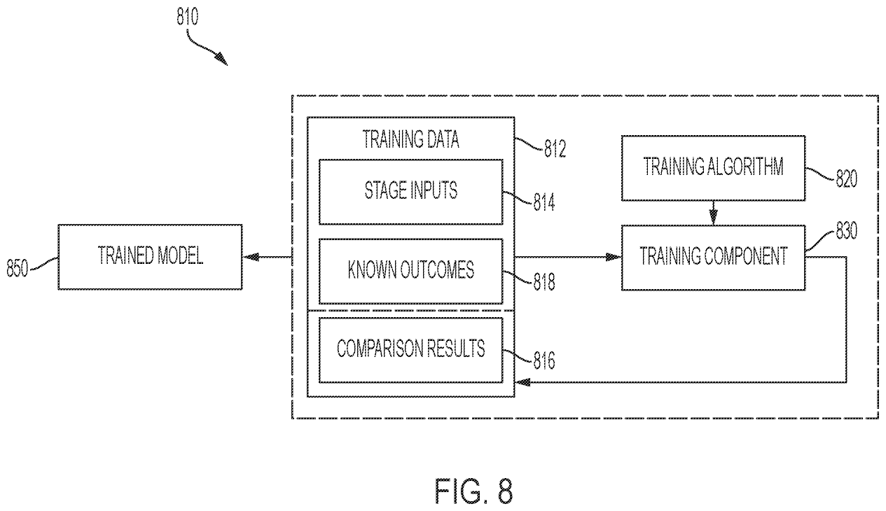

Method 600 uses one or more machine learning models. The machine learning models may be trained using techniques discussed with respect to FIG. 5 and/or FIG. 8.

At block 602, computing system 104 may identify an existing trained machine learning model. As discussed above, computing system 104 may include or be associated with various machine learning models 128a-n. One or more of the machine learning models may be optimized for generating predictions in the context of sports. Using a specific example, an existing trained machine learning model may be representative of an existing expected goals model that is trained to generate an expected goals output based on information associated with a shot attempt. The trained machine learning model may be identified at block 602 based on one or more of a prior selection, a prior use, a prior training, one or more categories of data (e.g., input data), a sport, a sport type, current match data, historical match data, and/or the like.

At block 604, computing system 104 may determine that the trained machine learning model is inaccurate for a class of situations. For example, for particular scenarios or situations in a game (e.g., an edge event), the accuracy of the existing machine learning model may be outside an expected range or beyond a tolerance. In some aspects, the determination that the trained machine learning model is inaccurate is performed based on a determination that a subset of the scenarios are beyond a threshold tolerance of accuracy. For example, computing system 104 can provide a first set of inputs to a machine learning model to generate a first prediction and a second set of inputs to the machine learning model to generate a second prediction. The computing system 104 can then compare each of the first and second predictions against expected ranges. For example, computing system 104 can determine that the first prediction is within an expected range of a first expected prediction and that the second prediction is outside of a second expected range of a second expected prediction.

Non-limiting examples of beyond a tolerance of accuracy include the measured accuracy being above a threshold. In some aspects, computing system 104 may determine that the trained machine learning is inaccurate, based on a user interacting with an interactive quality assurance interface (e.g., as discussed in reference to FIG. 3 and/or FIG. 4).

For example, computing system 104 may receive various prediction from a machine learning model. The computing system 104 may determine that the predictions associated with a subset of a class of scenarios (e.g., events) are beyond a threshold tolerance of accuracy. In response to the determination, the computing system 104, computing system 104 moves to block 606.

At block 606, computing system 104 may generate or receive a training data set that includes emphasized event data for the class of situations. In some aspects, intake module 508 may be configured to generate one or more training sets for the class of situations (e.g., edge events) using historical event data. For example, intake module 508 may be or include the edge event machine learning model, the edge event training model, etc., and may be configured to identify subsets of event data that correspond to specific class of situations.

The training data sets may include event data directed to the class of situations. Exemplary event data may include, but is not limited to clarity features (e.g., players between the shot and the goal), pressure (e.g., pressure being put on the shooter either time-wise or defensively), goalkeeper features (e.g., distance of goalkeeper to goal/shot/line of sight, angle of goalkeeper to shot, etc.), shot location features (e.g., distance and/or angle of shot to goal), shot type (e.g., volley, header, left foot, right foot, etc.), assist features (e.g., pullback, lay off, cross, throw in, etc.), previous action location (e.g., deflections), contextual features (e.g., shot follows a rebound, first touch, set play, etc.). In some aspects, intake module 508 may supplement the training data sets with normally distributed noise around coordinate related features. In some aspects, emphasized event data emphasizes events associated with the subset of the class of scenarios.

The subset of data directed to the class of situations may be a subset of the overall training data set. For instance, the event data may be limited by time, limited by particular events or actions, and/or a number of games or matches. For example, the data may be limited to the last few minutes of game play. In another example, the data may be applicable to certain events or actions such as passes or goals. In yet another example, the data is limited to certain games, for example, playoff games.

At block 608, computing system 104 may initialize an updated or new machine learning model by modifying weights, layers, biases, etc. of the existing machine learning model. In some aspects, the new machine learning model may be the same model type as the existing machine learning model. In operation, computing system 104 may identify the existing weights, layers, biases, etc. in existing machine learning model and may apply the existing weights, layers, biases, etc. to new machine learning model to warm up the model. One of the benefits of warming up the new machine learning model with weights from the existing machine learning model is that it maintains the accuracy of existing expected machine learning model for the vast majority of situations but improves predictions for the identified class of situations.

At block 610, computing system 104 may train the updated or new machine learning model using the training data. In some aspects, computing system 104 may train the new machine learning model using boosts of training data. As training progresses, the initial weights of the new machine learning model may be adjusted to account for the boost of training data. In some aspects, training includes modifying the weights based on the training data set.

At block 612, computing system 104 may deploy the updated or new machine learning model. For example, once the new machine learning model attains a desired level of accuracy, computing system 104 may deploy the new machine learning model in place of the existing machine learning model.

In some cases, computing system 104 can identify that an additional class of scenarios are associated with predictions that are beyond a tolerance of accuracy. In this case, blocks 604-612 may be repeated as necessary.

FIGS. 7A-7C are diagrams that illustrate exemplary categories of outlier events, in accordance with an aspect of the disclosed subject matter. FIG. 7A is a diagram 700 that illustrates an exemplary category of outlier events (e.g., edge events), in accordance with an aspect of the disclosed subject matter. Diagram 700 illustrates an example category of outlier events that include long range shots that are taken when the goalkeeper is also off position (e.g., goalkeeper comes up for a corner and has to track back). These shots may be defined using filters on distance of the shot from goal and the distance of the goalkeeper from goal.

FIG. 7B is a diagram 720 that illustrates an exemplary category of outlier events (e.g., edge events), in accordance with an aspect of the disclosed subject matter. Diagram 720 illustrates an example category of outlier events that includes medium range shots where the goalkeeper is caught further away from the shot than the shooter.

FIG. 7C is a diagram 740 that illustrates an exemplary category of outlier events (e.g., edge events), in accordance with an aspect of the disclosed subject matter. Diagram 740 illustrates an example category of outlier events that includes tight angle shots (e.g., shots taken from an acute angle to the goal). These types of shots usually involve close range shots that occur when an attacking player is forced wide by the defender and the space to shoot becomes narrower. They also involve the goalkeeper being slightly out of position and not where they would normally be expected to be (e.g., to be protecting their near post).

Such outlier events (e.g., edge events), as exemplified in FIGS. 7A-7C may be determined by a user or automated system. They may be provided as inputs to a machine learning model to re-train an existing model, as discussed herein.

FIG. 8 depicts a flow diagram 810 for training a machine learning model, in accordance with an aspect of the disclosed subject matter. As shown in flow diagram 810 of FIG. 8, training data 812 may include one or more of stage inputs 814 and known outcomes 818 related to a machine learning model to be trained. The stage inputs 814 may be from any applicable source including a component or set shown in the figures provided herein. The known outcomes 818 may be included for machine learning models generated based on supervised or semi-supervised training. An unsupervised machine learning model might not be trained using known outcomes 818. Known outcomes 818 may include known or desired outputs for future inputs similar to or in the same category as stage inputs 814 that do not have corresponding known outputs.

The training data 812 and a training algorithm 820 may be provided to a training component 830 that may apply the training data 812 to the training algorithm 820 to generate a trained machine learning model 850. According to an implementation, the training component 830 may be provided comparison results 816 that compare a previous output of the corresponding machine learning model to apply the previous result to re-train the machine learning model. The comparison results 816 may be used by the training component 830 to update the corresponding machine learning model. The training algorithm 820 may utilize machine learning networks and/or models including, but not limited to a deep learning network such as Deep Neural Networks (DNN), Convolutional Neural Networks (CNN), Fully Convolutional Networks (FCN) and Recurrent Neural Networks (RCN), probabilistic models such as Bayesian Networks and Graphical Models, and/or discriminative models such as Decision Forests and maximum margin methods, or the like. The output of the flow diagram 810 may be a trained machine learning model 850.

A machine learning model disclosed herein may be trained by adjusting one or more weights, layers, and/or biases during a training phase. During the training phase, historical or simulated data may be provided as inputs to the model. The model may adjust one or more of its weights, layers, and/or biases based on such historical or simulated information. The adjusted weights, layers, and/or biases may be configured in a production version of the machine learning model (e.g., a trained model) based on the training. Once trained, the machine learning model may output machine learning model outputs in accordance with the subject matter disclosed herein. According to an implementation, one or more machine learning models disclosed herein may continuously update based on feedback associated with use or implementation of the machine learning model outputs.

It should be understood that aspects in this disclosure are exemplary only, and that other aspects may include various combinations of features from other aspects, as well as additional or fewer features.

In general, any process or operation discussed in this disclosure that is understood to be computer-implementable, such as the processes illustrated in the flowcharts disclosed herein, may be performed by one or more processors of a computer system, such as any of the systems or devices in the exemplary environments disclosed herein, as described above. A process or process operation performed by one or more processors may also be referred to as an operation. The one or more processors may be configured to perform such processes by having access to instructions (e.g., software or computer-readable code) that, when executed by the one or more processors, cause the one or more processors to perform the processes. The instructions may be stored in a memory of the computer system. A processor may be a central processing unit (CPU), a graphics processing unit (GPU), or any suitable types of processing unit.

A computer system, such as a system or device implementing a process or operation in the examples above, may include one or more computing devices, such as one or more of the systems or devices disclosed herein. One or more processors of a computer system may be included in a single computing device or distributed among multiple computing devices. A memory of the computer system may include the respective memory of each computing device of the computing devices.

FIG. 9 depicts an exemplary a computing device, in accordance with an aspect of the disclosed subject matter. For example, the computing device 900 may be configured as a system according to exemplary aspects of this disclosure. In various aspects, any of the systems herein may be a computing device 900 including, for example, a data communication interface 920 for packet data communication. The computing device 900 also may include a central processing unit (“CPU”) or processor 902, in the form of one or more processors, for executing program instructions. The computing device 900 may include an internal communication bus 908, and a storage unit 906 (such as ROM, HDD, SDD, etc.) that may store data on a computer readable medium 922, although the computing device 900 may receive programming and data via network communications on network 105.

The computing device 900 may also have a memory 904 (such as RAM) storing instructions 924 for executing techniques presented herein, for example the methods described with respect to FIGS. 2 and 6, although the instructions 924 may be stored temporarily or permanently within other modules of computing device 900 (e.g., processor 902 and/or computer readable medium 922). The computing device 900 also may include input and output ports 912 and/or a display 910 to connect with input and output devices such as keyboards, mice, touchscreens, monitors, displays, etc. The various system functions may be implemented in a distributed fashion on a number of similar platforms, to distribute the processing load. Alternatively, the systems may be implemented by appropriate programming of one computer hardware platform.

Program aspects of the technology may be thought of as “products” or “articles of manufacture” typically in the form of executable code and/or associated data that is carried on or embodied in a type of machine-readable medium. “Storage” type media include any or all of the tangible memory of the computers, processors or the like, or associated modules thereof, such as various semiconductor memories, tape drives, disk drives and the like, which may provide non-transitory storage at any time for the software programming. All or portions of the software may at times be communicated through the Internet or various other telecommunication networks. Such communications, for example, may enable loading of the software from one computer or processor into another, for example, from a management server or host computer of the mobile communication network into the computer platform of a server and/or from a server to the mobile device. Thus, another type of media that may bear the software elements includes optical, electrical and electromagnetic waves, such as used across physical interfaces between local devices, through wired and optical landline networks and over various air-links. The physical elements that carry such waves, such as wired or wireless links, optical links, or the like, also may be considered as media bearing the software. As used herein, unless restricted to non-transitory, tangible “storage” media, terms such as computer or machine “readable medium” refer to any medium that participates in providing instructions to a processor for execution.

While the disclosed methods, devices, and systems are described with exemplary reference to transmitting data, it should be appreciated that the disclosed aspects may be applicable to any environment, such as a desktop or laptop computer, an automobile entertainment system, a home entertainment system, etc. Also, the disclosed aspects may be applicable to any type of Internet protocol.

It should be appreciated that in the above description of exemplary aspects of the invention, various features of the invention are sometimes grouped together in a single aspect, figure, or description thereof for the purpose of streamlining the disclosure and aiding in the understanding of one or more of the various inventive aspects. This method of disclosure, however, is not to be interpreted as reflecting an intention that the claimed invention requires more features than are expressly recited in each claim. Rather, as the following claims reflect, inventive aspects lie in less than all features of a single foregoing disclosed aspect. Thus, the claims following the Detailed Description are hereby expressly incorporated into this Detailed Description, with each claim standing on its own as a separate aspect of this invention.

Furthermore, while some aspects described herein include some but not other features included in other aspects, combinations of features of different aspects are meant to be within the scope of the invention, and form different aspects, as would be understood by those skilled in the art. For example, in the following claims, any of the claimed aspects can be used in any combination.

Thus, while certain aspects have been described, those skilled in the art will recognize that other and further modifications may be made thereto without departing from the spirit of the invention, and it is intended to claim all such changes and modifications as falling within the scope of the invention. For example, functionality may be added or deleted from the block diagrams and operations may be interchanged among functional blocks. Operations may be added or deleted to methods described within the scope of the present invention.

The above disclosed subject matter is to be considered illustrative, and not restrictive, and the appended claims are intended to cover all such modifications, enhancements, and other implementations, which fall within the true spirit and scope of the present disclosure. Thus, to the maximum extent allowed by law, the scope of the present disclosure is to be determined by the broadest permissible interpretation of the following claims and their equivalents, and shall not be restricted or limited by the foregoing detailed description. While various implementations of the disclosure have been described, it will be apparent to those of ordinary skill in the art that many more implementations are possible within the scope of the disclosure. Accordingly, the disclosure is not to be restricted except in light of the attached claims and their equivalents.

What is claimed is:

1. A method comprising:
receiving, from a machine learning model, predictions associated with a class of scenarios;
identifying, in response to receiving the predictions, a subset of the class of scenarios that are beyond a threshold tolerance of accuracy;
based on identifying the subset of the class of scenarios, generating, by a computing system, a training data set that includes emphasized event data from a plurality of historical sporting events, wherein the emphasized event data emphasizes events associated with the subset of the class of scenarios;
generating, by the computing system, an updated machine learning model by:
identifying weights of the machine learning model,
initializing the updated machine learning model using the weights, and
training the updated machine learning model using the training data set, wherein training the updated machine learning model comprises modifying the weights based on the training data set; and
deploying, by the computing system, the updated machine learning model.

2. The method of claim 1, further comprising:
receiving updated predictions, associated with the class of scenarios, from the updated machine learning model; and
outputting a visualization of the updated predictions.

3. The method of claim 2, further comprising:
identifying, from the updated predictions, an additional subset of the class of scenarios that are beyond the threshold tolerance of accuracy; and
based on identifying the additional subset of the class of scenarios, generating, by the computing system, an additional training data set that includes emphasized additional event data from the plurality of historical sporting events, wherein the emphasized additional event data emphasizes the additional subset of the class of scenarios.

4. The method of claim 3, wherein training the updated machine learning model using the training data set comprising:
sequentially exposing the updated machine learning model to boosts of training data comprising the training data set and the additional training data set.

5. The method of claim 1, wherein identifying the class of scenarios comprises:
receiving an indication from a user that the machine learning model is generating predictions beyond the threshold tolerance of accuracy.

6. The method of claim 1, wherein identifying the class of scenarios comprises:
providing a first set of inputs to the machine learning model to generate a first prediction;
providing a second set of inputs to the machine learning model to generate an additional prediction;
determining that the first prediction is within an expected range of a first expected prediction; and
determining the second prediction is outside of a second expected range of an second expected prediction.

7. The method of claim 1, wherein the emphasized event data is generated by:
providing initial training data used to train the machine learning model to an edge event machine learning model;
providing the subset of the class of scenarios to the edge event machine learning model; and
receiving the emphasized event data output by the edge event machine learning model based on the initial training data and the subset of the class of scenarios, wherein the emphasized event data is a subset of the initial training data weighted higher than in the initial training data.

8. A non-transitory computer readable medium configured to store processor-readable instructions, wherein when executed by a processor, the instructions perform operations comprising:
receiving, from a machine learning model, predictions associated with a class of scenarios;
identifying, in response to receiving the predictions, a subset of the class of scenarios that are beyond a threshold tolerance of accuracy;
based on identifying the subset of the class of scenarios, generating, by a computing system, a training data set that includes emphasized event data from a plurality of historical sporting events, wherein the emphasized event data emphasizes events associated with the subset of the class of scenarios;
generating, by the computing system, an updated machine learning model by:
identifying weights of the machine learning model,
initializing the updated machine learning model using the weights, and
training the updated machine learning model using the training data set, wherein training the updated machine learning model comprises modifying the weights based on the training data set; and
deploying, by the computing system, the updated machine learning model.

9. The non-transitory computer readable medium of claim 8, wherein when executed by a processor, the instructions perform operations comprising:
receiving updated predictions, associated with the class of scenarios, from the updated machine learning model; and
outputting a visualization of the updated predictions.

10. The non-transitory computer readable medium of claim 9, wherein when executed by a processor, the instructions perform operations comprising:
identifying, from the updated predictions, an additional subset of the class of scenarios that are beyond the threshold tolerance of accuracy; and
based on identifying the additional subset of the class of scenarios, generating, by the computing system, an additional training data set that includes emphasized additional event data from the plurality of historical sporting events, wherein the emphasized additional event data emphasizes the additional subset of the class of scenarios.

11. The non-transitory computer readable medium of claim 10, wherein training the updated machine learning model using the training data set comprising:
sequentially exposing the updated machine learning model to boosts of training data comprising the training data set and the additional training data set.

12. The non-transitory computer readable medium of claim 10, wherein identifying the class of scenarios comprises:
receiving an indication from a user that the machine learning model is generating predictions beyond the threshold tolerance of accuracy.

13. The non-transitory computer readable medium of claim 10, wherein identifying the class of scenarios comprises:
providing a first set of inputs to the machine learning model to generate a first prediction;
providing a second set of inputs to the machine learning model to generate a second prediction;
determining that the first prediction is within an expected range of a first expected prediction; and
determining the second prediction is outside of a second expected range of an second expected prediction.

14. The non-transitory computer readable medium of claim 10, wherein the emphasized event data is generated by:
providing initial training data used to train the machine learning model to an edge event machine learning model;
providing the subset of the class of scenarios to the edge event machine learning model; and
receiving the emphasized event data output by the edge event machine learning model based on the initial training data and the subset of the class of scenarios, wherein the emphasized event data is a subset of the initial training data weighted higher than in the initial training data.

15. A system comprising:
a processor; and
a non-transitory computer readable medium having program instructions stored thereon, which, when executed by the processor, cause the system to perform operations comprising:
receiving, from a machine learning model, predictions associated with a class of scenarios;
identifying, in response to receiving the predictions, a subset of the class of scenarios that are beyond a threshold tolerance of accuracy;
based on identifying the subset of the class of scenarios, generating, by a computing system, a training data set that includes emphasized event data from a plurality of historical sporting events, wherein the emphasized event data emphasizes events associated with the subset of the class of scenarios;
generating, by the computing system, an updated machine learning model by:
identifying weights of the machine learning model,
initializing the updated machine learning model using the weights, and
training the updated machine learning model using the training data set, wherein training the updated machine learning model comprises modifying the weights based on the training data set; and
deploying, by the computing system, the updated machine learning model.

16. The system of claim 15, wherein when executed by the processor, the program instructions cause the system to perform operations comprising:
receiving updated predictions, associated with the class of scenarios, from the updated machine learning model; and
outputting a visualization of the updated predictions.

17. The system of claim 16, wherein when executed by the processor, the program instructions cause the system to perform operations comprising:
identifying, from the updated predictions, an additional subset of the class of scenarios that are beyond the threshold tolerance of accuracy; and
based on identifying the additional subset of the class of scenarios, generating, by the computing system, an additional training data set that includes emphasized additional event data from the plurality of historical sporting events, wherein the emphasized additional event data emphasizes the additional subset of the class of scenarios.

18. The system of claim 17, wherein training the updated machine learning model using the training data set comprising:
sequentially exposing the updated machine learning model to boosts of training data comprising the training data set and the additional training data set.

19. The system of claim 16, wherein identifying the class of scenarios comprises:
receiving an indication from a user that the machine learning model is generating predictions beyond the threshold tolerance of accuracy.

20. The system of claim 16, wherein identifying the class of scenarios comprises:
providing a first set of inputs to the machine learning model to generate a first prediction;
providing a second set of inputs to the machine learning model to generate a second prediction;
determining that the first prediction is within an expected range of a first expected prediction; and
determining the second prediction is outside of a second expected range of a second expected prediction.
